(19) United States
(12) Patent Application Publication
(10) Pub. No.: US 2018/0182462 A1
(43) Pub. Date: Jun. 28, 2018

(54) SEMICONDUCTOR STORAGE DEVICE

(71) Applicant: LAPIS SEMICONDUCTOR CO., LTD., KANAGAWA (JP)

(72) Inventor: JUNYA OGAWA, KANAGAWA (JP)

(21) Appl. No.: 15/844,221

(22) Filed: Dec. 15, 2017

(30) Foreign Application Priority Data
Dec. 22, 2016 (JP) 2016-249499

(51) Int. Cl. G11C 16/08; G11C 16/32

(52) U.S. Cl. CPC G11C 16/08; G11C 16/32

(57) ABSTRACT

A semiconductor storage device, that includes: a pre-decoder circuit that decodes an input address signal and generates a first pre-decode signal corresponding to a first address indicated by the address signal; a control signal generation circuit that generates a control signal based on the address signal, the control signal indicating whether the first address is taken as an access target, or whether a second address, which is a next address consecutive from the first address, is taken as the access target; and a selection circuit that, based on the control signal, selects and outputs one of the first pre-decode signal or a second pre-decode signal corresponding to the second address.

### CROSS-REFERENCE TO RELATED APPLICATION

This application claims priority under 35 USC 119 from Japanese Patent Application No. 2016-249499, filed on Dec. 22, 2016, the disclosure of which is incorporated by reference herein.

### BACKGROUND

### Technical Field

The present disclosure relates to a semiconductor storage device.

### Related Art

A semiconductor storage device (semiconductor memory) is known that utilizes a parallel bus as a single interface in order to achieve high speed access. In cases in which a parallel bus is utilized, at least several tens of signal lines need to be connected in order to connect the semiconductor storage device to peripheral devices, and so it is accordingly difficult to achieve high device integration and a compact package. However, semiconductor storage devices utilizing a serial bus are able to achieve high device integration and a compact package even though there is a drop in communication speed compared to semiconductor storage devices utilizing a parallel bus. In recent years, progress is being made with various developments to enable high speed access to be achieved in semiconductor storage devices that use serial communication. For example, it is possible to shorten the access time by dividing a memory cell array into plural memory banks, and executing specific operations in each memory bank at the same time by transmitting commands to each of the memory banks at the same time.

As technology related to semiconductor storage devices equipped with plural memory banks, Japanese Patent Application Laid-Open (JP-A) No. 2012-190501, for example, describes a semiconductor storage device including a memory cell array with two simultaneously accessible memory banks, and a controller to control writing and reading of data to and from the memory cell array. In such a semiconductor storage device, operation to read data is performed in the following manner.

First, in response to a command latch enable signal, the controller decodes a received read command, then, in response to an address latch enable signal, the controller sets a column address and a row address in an address register. The controller than determines whether or not the column address information that was read falls within the column address range of the left page of the memory bank. When it has been determined that the column address that was read falls within the left page, the controller sets flag=0, and when determined that the column address that was read falls within the right page, the controller sets flag=1. The controller then presets the read mode.

The controller then receives a start command read in response to the command latch enable signal, and determines whether or not the command is a first read instruction or a second read instruction. When the command is the first read instruction, the controller executes a first read operation in a word line selection circuit to select an n^{th} word line in one of the memory banks and to select the (n+1)^{th} or the (n−1)^{th} word line in the other memory bank. However, when the command is the second read instruction, the controller executes a second read operation in the word line selection circuit to select an n^{th} word line in the one memory bank and to select the n^{th} word line in the other memory bank. Reading of the left and right pages is performed by the word line selection. Data that has been transmitted to a page buffer is sequentially transmitted to a data register in sequence by incrementing the page address.

In semiconductor storage devices that utilize a serial interface, such as a serial peripheral interface (SPI), data reading is performed in sequence from consecutive addresses in a memory region in synchronization to a clock signal. In this manner, in a serial communication semiconductor storage device, when the position to start reading in a memory region corresponding to the leading address out of consecutive addresses approaches the top position of the memory region corresponding to the next address, the timing to read from the top position of the memory region corresponding to the next address is delayed, and there is a concern that data reading might no longer be synchronizable to the clock signal.

In order to avoid such a problem, in a serial communication semiconductor storage device, a memory cell array is divided into two memory banks, and reading of data is performed from a memory region corresponding to an input address in one of the memory banks, and reading of data is performed from a memory region corresponding to the next address to the input address in the other of the memory banks.

FIG. 1 is a block diagram illustrating an example of a configuration of a traditional pre-decoder that, as described above, performs reading of data from the next address consecutive to the input address. This pre-decoder includes an internal address generation circuit 501, a pre-decoder circuit 502, and a buffer circuit 503. The internal address generation circuit 501 generates an internal address signal ADx based on an input address signal AD, and supplies the internal address signal ADx to the pre-decoder circuit 502. The pre-decoder circuit 502 generates a pre-decode signal PD pre-decoded from the internal address signal ADx, and supplies the pre-decode signal PD to the buffer circuit 503. The buffer circuit 503 buffers the pre-decode signal PD and supplies the pre-decode signal PD as an output signal D to a subsequent stage decoder (not illustrated in the drawings).

In the traditional pre-decoder as described above, the pre-decoder circuit 502 waits for the finalization of the internal address signal ADx generated in the internal address generation circuit 501 before starting pre-decoder processing. Namely, finalization of the internal address signal ADx acts as the trigger for operation of the pre-decoder circuit 502, and so the pre-decoder circuit 502 is not able to start the pre-decoder processing until the internal address signal ADx has been finalized. Thus, in a traditional pre-decoder, the time from input of the address signal AD to the internal address generation circuit 501 to the output of the output signal D from the buffer circuit 503 (namely, the pre-decoding duration) is a long time, and it is difficult to implement a satisfactory access time as memory access times become shorter with increasing clock frequencies.

### SUMMARY

According to an aspect of the present disclosure, 1. a semiconductor storage device, includes: a pre-decoder circuit that decodes an input address signal and generates a first pre-decode signal corresponding to a first address indicated by the address signal; a control signal generation circuit that generates a control signal based on the address signal, the control signal indicating whether the first address is taken as an access target, or whether a second address, which is a next address consecutive from the first address, is taken as the access target; and a selection circuit that, based on the control signal, selects and outputs one of the first pre-decode signal or a second pre-decode signal corresponding to the second address.

### BRIEF DESCRIPTION OF THE DRAWINGS

Exemplary embodiments will be described in detail based on the following figures, wherein:

FIG. 1 is a block diagram illustrating a configuration of a traditional pre-decoder;

FIG. 2 is a block diagram illustrating a configuration of a semiconductor storage device according to an exemplary embodiment of the present disclosure;

FIG. 3 is a block diagram illustrating a configuration of a pre-decoder according to an exemplary embodiment of the present disclosure;

FIG. 4 is a diagram illustrating functionality of a selection circuit according to an exemplary embodiment of the present disclosure;

FIG. 5 is an equivalent circuit diagram illustrating an example of a configuration of a selection circuit according to an exemplary embodiment of the present disclosure;

FIG. 6 is a timing chart illustrating an example of operation of a pre-decoder of the present disclosure; and

FIG. 7 is a diagram illustrating a configuration of a carry signal generation circuit and an address input line of a pre-decoder circuit 12 according to an exemplary embodiment of the present disclosure.

### DETAILED DESCRIPTION

Explanation follows regarding an exemplary embodiment of the present disclosure, with reference to the drawings. Note that substantially the same or equivalent configuration elements or parts are appended with the same reference signs in each of the drawings.

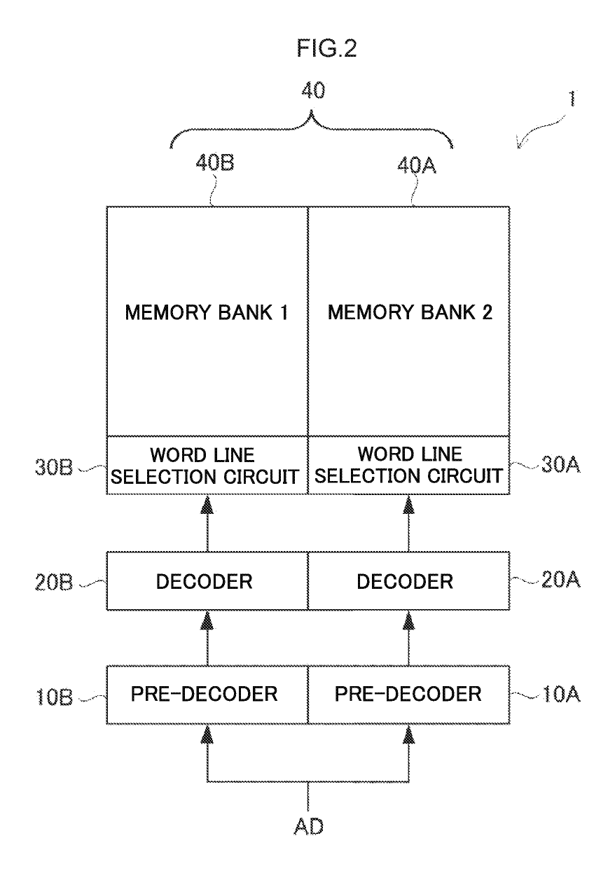

FIG. 2 is a block diagram illustrating a configuration of a semiconductor storage device 1 according to an exemplary embodiment of the present disclosure. The semiconductor storage device 1 is a semiconductor memory that performs writing and reading of data to and from a memory cell using serial communication with a serial bus, such as a serial peripheral interface (SPI). For example, when performing data reading in the semiconductor storage device 1, the reading is synchronized to a clock signal, and data is read sequentially from consecutive addresses in a memory region.

The semiconductor storage device 1 includes a memory cell array 40, to and from which data reading and writing is performed. The memory cell array 40 includes two memory banks 40A, 40B. Pre-decoders 10A, 10B, decoders 20A, 20B, and word line selection circuits 30A, 30B are provided so as to correspond to the respective memory banks 40A, 40B. The semiconductor storage device 1 according to the present exemplary embodiment enables independent access to the memory banks 40A, 40B. For example, by transmitting commands to the memory banks 40A, 40B at the same time, specific operations can be executed at the same time in the memory banks 40A, 40B, enabling the access time to be shortened.

Moreover, dividing the memory cell array 40 into the two memory banks 40A, 40B enables independent access to the memory banks 40A, 40B. It is possible to read data from a memory region corresponding to an input address in the one memory bank 40B while also reading data from a memory region corresponding to the next address consecutive to the input address in the other memory bank 40A, even when the start position for reading in a memory region corresponding to the leading address out of the consecutive addresses approaches the top position of the memory region corresponding to the next address. This enables a delay to be avoided in the timing to read the top position of the memory region specified by the next address.

In the semiconductor storage device 1 according to the present exemplary embodiment, from out of the memory banks 40A and 40B, the memory bank 40A is a memory bank from which data is readable from a memory region corresponding to the next address to the address (the input address) indicated by the address signal AD.

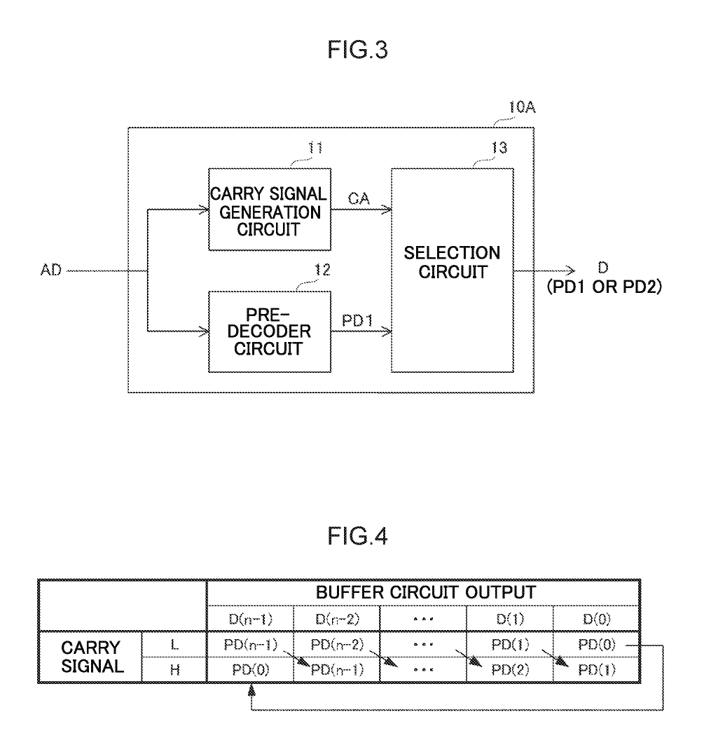

FIG. 3 is a block diagram illustrating configuration of the pre-decoder 10A associated with the memory bank 40A from which data is readable from the memory region corresponding to the next address to the input address. The pre-decoder 10A is configured including a carry signal generation circuit 11, a pre-decoder circuit 12, and a selection circuit 13. The address signal AD specifying the access position in the memory region is input to the carry signal generation circuit 11 and the pre-decoder circuit 12.

The carry signal generation circuit 11 sets a signal level of a carry signal CA to high level or low level based on the address signal AD. The carry signal generation circuit 11 generates the carry signal CA at low level when data is to be read from the input address indicated by the address signal AD, and generates the carry signal CA at high level when data is to be read from the next address consecutive to the input address. Namely, the carry signal generation circuit 11 generates the carry signal CA, indicating whether or not the next address consecutive to the input address is the access target, as a control signal to control a selection operation in the selection circuit 13.

The pre-decoder circuit 12 pre-decodes the address signal AD and generates a first pre-decode signal PD1. The first pre-decode signal PD1 is a signal corresponding to the input address indicated by the address signal AD. The pre-decoder circuit 12 supplies the generated pre-decode signal PD to the selection circuit 13.

FIG. 4 is a diagram illustrating functionality of the selection circuit 13. The first pre-decode signal PD1 and the carry signal CA are bit strings of n bits, and are input to the selection circuit 13. The value of the first bit in the first pre-decode signal PD1 supplied from the pre-decoder circuit 12 is denoted by PD(0), the value of the second bit thereof is denoted by PD(1), and the value of the most significant bit is denoted PD(n−1). Further, the value of the first bit of an output signal D output from the selection circuit 13 is denoted by D(0), the value of the second bit is denoted by D(1), and the value of the most significant bit is denoted D(n−1).

The selection circuit 13 outputs the values of each of the bits of the first pre-decode signal PD1 supplied from the pre-decoder circuit 12 without modification as the output signal D in cases in which the level of the carry signal CA is low level. Namely, in cases in which the level of the carry signal CA is low level, the selection circuit 13 selects the first pre-decode signal PD1, and sets the values of each of the bits of the output signal of the selection circuit 13 such that D(0)=PD(0), D(1)=PD(1), D(n−2)=PD(n−2), D(n−1)=PD(n−1).

However, in cases in which the level of the carry signal CA is high level, the selection circuit 13 generates a second pre-decode signal PD2 in which the values of each of the bits of the first pre-decode signal PD1 supplied from the pre-decoder circuit 12 are shifted to those of another bit, and outputs the second pre-decode signal PD2 as the output signal D. Namely, in cases in which the level of the carry signal CA is high level, the selection circuit 13 generates and selects the second pre-decode signal PD2, and sets the values of each of the bits of the output signal D of the selection circuit 13 such that D(0)=PD(1), D(1)=PD(2), D(n−2)=PD(n−1), and D(n−1)=PD(0). In this manner, the second pre-decode signal PD2 has bits values of each of the bits of the first pre-decode signal PD1 shifted by 1, and corresponds to the next address to the input address. The output signal D output from the selection circuit 13 (the first pre-decode signal PD1 or the second pre-decode signal PD2) is supplied to the decoder 20A of the subsequent stage.

Thus, based on the carry signal CA, the selection circuit 13 selectively outputs the first pre-decode signal PD1 corresponding to the input address, or the second pre-decode signal PD2 corresponding to the next address to the input address.

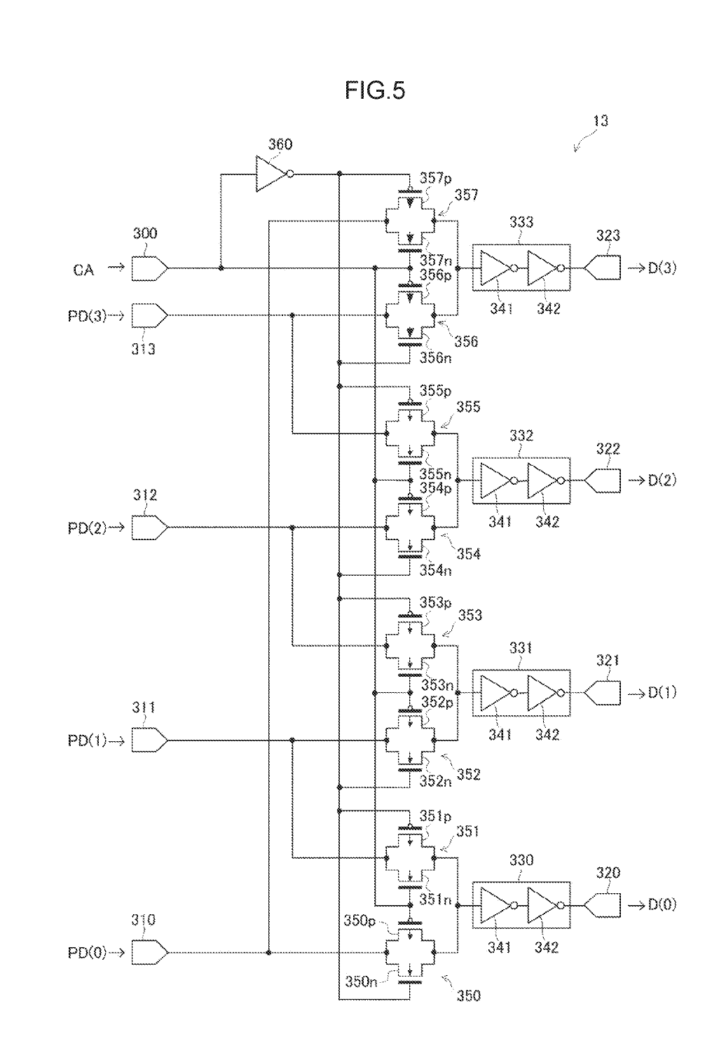

FIG. 5 is an equivalent circuit diagram illustrating an example of a configuration of the selection circuit 13. Note that although FIG. 5 illustrates an example of a configuration for a case in which the first pre-decode signal PD1 input to the selection circuit 13 and the output signal D output from the selection circuit 13 are each configured with four bits, the number of bits in the first pre-decode signal PD1 and the output signal D may be changed as appropriate.

The selection circuit 13 includes a control terminal 300 input with the carry signal CA, input terminals 310 to 313 respectively input with the values of the first bit PD(0) to the fourth bit PD(3) of the first pre-decode signal PD1, and output terminals 320 to 323 respectively outputting the values of the first bit D(0) to the fourth bit D(3) of the output signal D. Buffer circuits 330 to 333 that are each configured by serially connected inverters 341 and 342 are respectively connected to the output terminals 320 to 323.

The selection circuit 13 includes transfer gates 350 to 357 that are each configured by combining an n-channel transistor (referred to below as nMOS) and a p-channel transistor (referred to below as pMOS).

The input terminal of the transfer gate 350 is connected to the input terminal 310, and the output terminal of the transfer gate 350 is connected to the output terminal 320 via the buffer circuit 330. In the transfer gate 350, the gate of the nMOS 350n is connected to the control terminal 300 via the inverter 360, and the gate of the pMOS 350p is directly connected to the control terminal 300.

The input terminal of the transfer gate 351 is connected to the input terminal 311, and the output terminal of the transfer gate 351 is connected to the output terminal 320 via the buffer circuit 330. In the transfer gate 351, the gate of the nMOS 351n is directly connected to the control terminal 300, and the gate of the pMOS 351p is connected to the control terminal 300 via the inverter 360.

The input terminal of the transfer gate 352 is connected to the input terminal 311, and the output terminal of the transfer gate 352 is connected to the output terminal 321 via the buffer circuit 331. In the transfer gate 352, the gate of the nMOS 352n is connected to the control terminal 300 via the inverter 360, and the gate of the pMOS 352p is directly connected to the control terminal 300.

The input terminal of the transfer gate 353 is connected to the input terminal 312, and the output terminal of the transfer gate 353 is connected to the output terminal 321 via the buffer circuit 331. In the transfer gate 353, the gate of the nMOS 353n is directly connected to the control terminal 300, and the gate of the pMOS 353p is connected to the control terminal 300 via the inverter 360.

The input terminal of the transfer gate 354 is connected to the input terminal 312, and the output terminal of the transfer gate 354 is connected to the output terminal 322 via the buffer circuit 332. In the transfer gate 354, the gate of the nMOS 354n is connected to the control terminal 300 via the inverter 360, and the gate of the pMOS 354p is directly connected to the control terminal 300.

The input terminal of the transfer gate 355 is connected to the input terminal 313, and the output terminal of the transfer gate 355 is connected to the output terminal 322 via the buffer circuit 332. In the transfer gate 355, the gate of the nMOS 355n is directly connected to the control terminal 300, and the gate of the pMOS 355p is connected to the control terminal 300 via the inverter 360.

The input terminal of the transfer gate 356 is connected to the input terminal 313, and the output terminal of the transfer gate 356 is connected to the output terminal 323 via the buffer circuit 333. In the transfer gate 356, the gate of the nMOS 356n is connected to the control terminal 300 via the inverter 360, and the gate of the pMOS 356p is directly connected to the control terminal 300.

The input terminal of the transfer gate 357 is connected to the input terminal 310, and the output terminal of the transfer gate 357 is connected to the output terminal 323 via the buffer circuit 333. In the transfer gate 357, the gate of the nMOS 357n is directly connected to the control terminal 300, and the gate of the pMOS 357p is connected to the control terminal 300 via the inverter 360.

In the selection circuit 13 having the configuration described above, when the level of the carry signal CA input to the control terminal 300 is low level, the transfer gates 350, 352, 354, and 356 adopt the ON state and the transfer gates 351, 353, 355, and 357 adopt the OFF state. The first bit value PD(0) of the pre-decoder signal PD input to the input terminal 310 is thereby buffered in the buffer circuit 330, and output to the output terminal 320. Further, the second bit value PD(1) of the pre-decoder signal PD input to the input terminal 311 is buffered in the buffer circuit 331, and output to the output terminal 321. Further, the third bit value PD(2) of the pre-decoder signal PD input to the input terminal 312 is buffered in the buffer circuit 332, and output to the output terminal 322. Further, the fourth bit value PD(3) of the pre-decoder signal PD input to the input terminal 313 is buffered in the buffer circuit 333, and output to the output terminal 323.

On the other hand, in cases in which the level of the carry signal CA input to the control terminal 300 is high level, the transfer gates 351, 353, 355, and 357 adopt the ON state and the transfer gates 350, 352, 354, and 356 adopt the OFF state. Thus, the first bit value PD(0) of the pre-decoder signal PD input to the input terminal 310 is buffered in the buffer circuit 333, and output to the output terminal 323. Further, the second bit value PD(1) of the pre-decoder signal PD input to the input terminal 311 is buffered in the buffer circuit 330, and output to the output terminal 320. Further, the third bit value PD(2) of the pre-decoder signal PD input to the input terminal 312 is buffered in the buffer circuit 331, and output to the output terminal 321. Further, the fourth bit value PD(3) of the pre-decoder signal PD input to the input terminal 313 is buffered in the buffer circuit 332, and output to the output terminal 322.

Note that buffering in the buffer circuits 330, 331, 332, and 333 includes processing to adjust the amplitude and drive performance of the signal input to the buffer circuits so as to be appropriate for the subsequent stage decoder 20A.

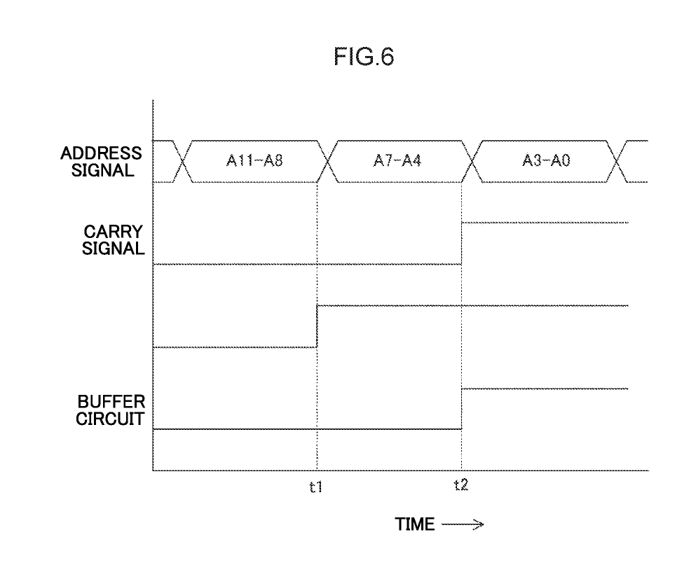

FIG. 6 is a timing chart illustrating an example of operation of the pre-decoder 10A. The address signal AD configured from plural bits A0 to A11 is synchronized to the clock signal and input to the pre-decoder 10A in sequence from the high order bit A11. The address signal AD specifies the memory region which is to be the access target. Further, in FIG. 6, in relation to the carry signal, high level means the level of the carry signal is finalized. Further, in relation to the pre-decoder circuit, high level means that pre-decoder processing is executed. Further, in relation to the selection circuit, high level means that the output signal is output.

Information to indicate the input address is included in the upper order bits A11 to A8 of the address signal AD. Thus, in the pre-decoder circuit 12, at time t1 when the high order bits A11 to A8 of the address signal AD have been input to the pre-decoder circuit 12, it is possible to pre-decode the address signal AD and to generate the first pre-decode signal PD1.

However, information indicating whether or not to read data from the next address consecutive to the input address is included in bits A7 to A4 of the address signal AD. The carry signal generation circuit 11 finalizes the level of the carry signal CA at the time t2 when the values up to bit A4 of the address signal AD have been input. When the level of the carry signal CA has been finalized, the selection circuit 13 outputs, as the output signal D according to the level of the carry signal CA, the first pre-decode signal PD1 corresponding to the input address and the second pre-decode signal PD2 corresponding to the next address to the input address, and supplies the output signal D to the subsequent stage decoder 20A.

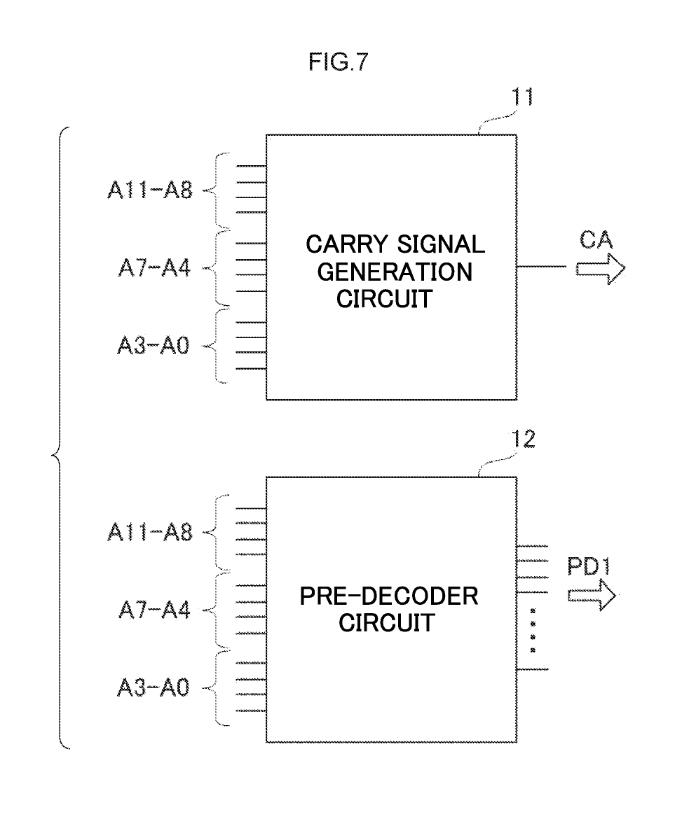

Note that, as illustrated in FIG. 7, the carry signal generation circuit 11 and the pre-decoder circuit 12 may include address input lines to input each of the bits A0 to A11 of the address signal AD individually. The number of the address input lines may be changed as appropriate, and, for example, may be a single line. Further, in the present exemplary embodiment, the pre-decoder circuit 12 includes n output lines to output values of each bit of the first pre-decode signal PD1 configured from n-bits at the same time.

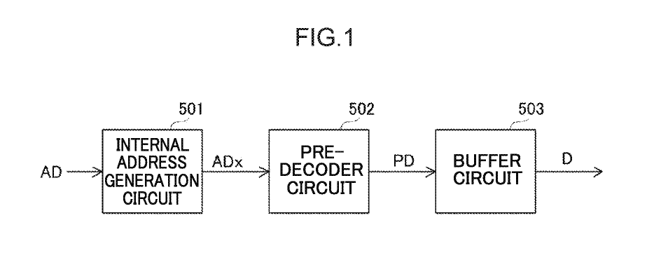

As described above, in the semiconductor storage device 1 according to the exemplary embodiment of the present disclosure, based on the carry signal CA, the selection circuit 13 selects and outputs either the first pre-decode signal PD1 corresponding to the input address or the second pre-decode signal PD2 corresponding to the next address to the input address, enabling the pre-decoder circuit 12 to be operated using the address signal AD as a trigger. Thus, finalization of an internal address signal ADx becomes the trigger to operate a pre-decoder circuit 502, enabling the pre-decoding duration to be shortened compared to the configuration illustrated in FIG. 1.

Note that the carry signal generation circuit 11 is an example of a control signal generation circuit of the present disclosure, and the carry signal CA is an example of a control signal of the present disclosure. The pre-decoder circuit 12 is an example of a pre-decoder circuit of the present disclosure. The selection circuit 13 is an example of a selection circuit of the present disclosure. The transfer gates 350 to 357 are examples of switch circuits.

The present disclosure is able to provide a semiconductor storage device capable of shortening the pre-decoding duration.

What is claimed is:

1. A semiconductor storage device, comprising:
a pre-decoder circuit that decodes an input address signal and generates a first pre-decode signal corresponding to a first address indicated by the address signal;
a control signal generation circuit that generates a control signal based on the address signal, the control signal indicating whether the first address is taken as an access target, or whether a second address, which is a next address consecutive from the first address, is taken as the access target; and
a selection circuit that, based on the control signal, selects and outputs one of the first pre-decode signal or a second pre-decode signal corresponding to the second address.

2. The semiconductor storage device of claim 1, wherein:
the first pre-decode signal includes a plurality of bits; and
the second pre-decode signal is a signal in which values of respective bit positions of the first pre-decode signal are shifted to a bit position other than an original bit position.

3. The semiconductor storage device of claim 2, wherein the selection circuit includes:
a plurality of input terminals that are input with respective values of each of the bits of the first pre-decode signal;
a plurality of output terminals from which respective values of each of the bits of one of the first pre-decode signal or the second pre-decode signal are output; and
a plurality of switch circuits that, based on the control signal, switch connections between the plurality of input terminals and the plurality of output terminals.

4. The semiconductor storage device of claim 3, wherein the selection circuit further includes a buffer circuit connected to each of the plurality of output terminals.

5. The semiconductor storage device of claim 1, wherein:
the address signal includes a plurality of bits that are input to the pre-decoder circuit in sequence from higher order bits; and
the pre-decoder circuit starts to generate the first pre-decode signal at a point in time at which a part of the address signal has been input.

6. The semiconductor storage device of claim 1, further comprising a memory cell array including a plurality of memory banks, wherein the pre-decoder circuit, the control signal generation circuit, and the selection circuit correspond to one of the plurality of memory banks.
